(19) United States
(12) Patent Application Publication
(10) Pub. No.: US 2005/0134877 A1
(43) Pub. Date: Jun. 23, 2005

(54) Color image processing device and color image processing method

(75) Inventor: Kenichi Kamada, Nagaokakyo-shi (JP)

Correspondence Address: HOGAN & HARTSON L.L.P., 500 S. GRAND AVENUE, SUITE 1900, LOS ANGELES, CA, 90071-2611, US

(73) Assignee: MURATA KIKAI KABUSHIKI KAISHA

(21) Appl. No.: 10/990,793

(22) Filed: Nov. 17, 2004

(30) Foreign Application Priority Data
Dec. 17, 2003 (JP) 2003-420184
Dec. 17, 2003 (JP) 2003-420185

(51) Int. Cl. G06F 15/00; G03F 3/08

(52) U.S. Cl. 358/1.9; 358/518; 382/167

(57) ABSTRACT

A color image processing device includes a first transfer control unit which transfers image data of a prescribed volume for each prescribed unit, a compressing and encoding unit which compresses and encodes the image data, a storage unit which stores the data compressed and encoded by the compressing and encoding unit, and a second transfer control unit which transfers the compressed and encoded data from the compressing and encoding unit to the storage unit. Each time when the first transfer control unit transfers the image data of the prescribed unit, the second transfer control unit divides and transfers the compressed and encoded data.

### BACKGROUND OF THE INVENTION

1. Field of the Invention

The present invention relates to a color image processing device which compresses and encodes image data.

2. Description of the Related Art

As a color image processing device, for example, a copy machine, a scanner, a printer, a facsimile machine and a multifunction peripheral having a combination of these machines are conventionally known. Such a conventional color image processing device generates Red, Green and Blue (RGB) data by using a scanner function.

In case of compressing and encoding the RGB data under a Joint Photographic Experts Group (JPEG) method, the RGB data is converted into YCC data (a luminance color difference signal). Then, the YCC data is compressed and encoded by units of blocks (for example, 64 pixels of 8*8). Accordingly, a calculation amount can be reduced and an effect of the compression can be increased.

The RGB data is transmitted by a Direct Memory Access (DMA) transfer to an image processing module which carries out a JPEG compressing process. After a compressing and encoding process is carried out, the RGB data is transferred to an output memory by the DMA transfer again.

The image processing module includes a signal processing unit which executes a prescribed processing on data of units of blocks. For example, in such an image processing module, at a point of time when a signal processing in the signal processing unit completes, in case a DMA request is generated from a DMA request control unit of an input side or an output side, the signal processing in the signal processing unit is suspended. Accordingly, even in an image processing module ranked low in a priority order, abnormal data can be prevented from generating.

However, the conventional color image processing device has the following problem (first problem). The above-described DMA transfer is carried out via a general-purpose bus used not only by the image processing module but also by another system or the like. Therefore, the transfer of image data to the image processing module and the transfer of the image data from the image processing module are required to be carried out by controlling timing so that the general-purpose bus can be used by the other system. However, a data volume of the image data changes by being compressed and encoded. Thus, the data volume cannot be grasped and the transfer timing for transferring the image data from the image processing module is difficult to be controlled.

The conventional image processing device also has the following problem (second problem). As described above, since the JPEG compressing process is carried out by units of blocks, the timing of the data transfer between each of the image processing modules becomes complicated and difficult to be controlled.

### SUMMARY OF THE INVENTION

The present invention has been made in consideration of the above-described circumstances. A first advantage of the present invention is to provide a color image processing device which can carry out a data transfer at appropriate times.

A second advantage of the present invention is to provide a color image processing device which can simplify a transfer control process and can carry out a compressing and encoding process efficiently.

According to a first aspect of the present invention, a color image processing device includes a first transfer control unit, a compressing and encoding unit, a storage unit and a second transfer control unit. The first transfer control unit transfers image data of a prescribed volume for each prescribed unit. The compressing and encoding unit compresses and encodes the image data. The storage unit stores the compressed and encoded data. The second transfer control unit transfers the compressed and encoded data from the compressing and encoding unit to the storage unit. The second transfer control unit divides and transfers the compressed and encoded data each time when the first transfer control unit transfers the image data of a prescribed unit.

Accordingly, the compressed and encoded data can be divided and transferred at appropriate times. Further, the first transfer control unit and the second transfer control unit can transfer the image data by using a general-purpose bus. According to the present invention, even in such a case, the data is divided appropriately and transferred. Therefore, the general-purpose bus is not occupied by the data and the general-purpose bus can be shared with another system.

According to an aspect of the present invention, in the color image processing device, each time when the first transfer control unit transfers a prescribed unit of the image data, the first transfer control unit can transmit an interruption signal to the second transfer control unit. Each time when the second transfer control unit receives the interruption signal from the first transfer control unit, the second transfer control unit can stop the transfer of the data.

According to an aspect of the present invention, in the color image processing device, when the first transfer control unit finishes transferring all of the image data of the prescribed volume, the first transfer control unit can transmit an end signal to the second transfer control unit. After receiving the end signal from the first transfer control unit, until receiving a compression and encoding end signal from the compressing and encoding unit, the second transfer control unit can continue to transfer the image data.

Further, any combinations of the above-described constituent elements and the conversions of the expression of the present invention between a method, a device, a system, a recording medium, a computer program or the like are also effective as an embodiment of the present invention.

As described above, according to the present invention, the image processing device can transfer the data at appropriate times.

According to a second aspect of the present invention, a color image processing device includes a first storage unit, a transfer control unit, a second storage unit and a compressing and encoding unit. The first storage unit stores image data of color components expressed by a plurality of components. The transfer control unit transfers the image data. The second storage unit stores the image data transferred from the first storage unit by the transfer control unit, for each of the plurality of components. The compressing and encoding unit compresses and encodes the image data by units of blocks. The transfer control unit reads from the second storage unit, the image data of units of blocks for all of the plurality of the components, respectively. Then, the transfer control unit transfers the image data to the compressing and encoding unit.

As described above, the image data stored once in the second storage unit is read by units of blocks. Accordingly, the transfer process to the compressing and encoding unit can be carried out efficiently. Since the color image processing device includes the second storage unit, the image data can be transferred freely from the first storage unit without considering the timing or the like. As a result, a control process can be simplified.

The compressing and encoding unit can include a conversion unit for converting image data of a certain color space into image data of another color space. Therefore, the compressing and encoding unit can compress and encode the image data of the other color space. Here, a certain color space is RGB data or the like, and the other color space is YCC data, Lab data or the like. Further, the compressing and encoding unit can compress and encode the RGB data directly.

The transfer control unit can carry out a DMA transfer of the image data between the first storage unit and the second storage unit.

The color image processing device of the present invention can further include an access unit which controls the writing of the image data to the second storage unit and the reading of the image data from the second storage unit. The second storage unit includes a plurality of banks. The plurality of the banks store the image data for each of the plurality of the components, respectively. The plurality of the banks are accessed by the access unit in accordance with a row address and a column address. The access unit can write the image data into the second storage unit so that the image data of units of blocks is stored in the same row address.

By making the writing as described above, as to be described later, the image data can be read rapidly from the second storage unit.

According to an aspect of the present invention, in the color image processing device, with the row address fixed, the access unit can read the image data of units of blocks from each of the plurality of the banks and transfer the image data to the compressing and encoding unit.

As described above, by reading the image data with the row address fixed, a period of time required for reading the image data can be reduced.

As described above, according to the present invention, the image processing device can simplify the transfer control process and carry out the compressing and encoding process efficiently.

### BRIEF DESCRIPTION OF THE SEVERAL VIEWS OF THE DRAWINGS

FIG. 1 is a functional block diagram showing a color image processing device according to an embodiment of the present invention.

FIG. 2 schematically shows a data transfer carried out in the color image processing device.

FIG. 3 is a flowchart showing processing procedures of a first DMA controller and a second DMA controller.

FIGS. 4A and 4B show an inner configuration of a second storage unit.

### DETAILED DESCRIPTION OF THE INVENTION

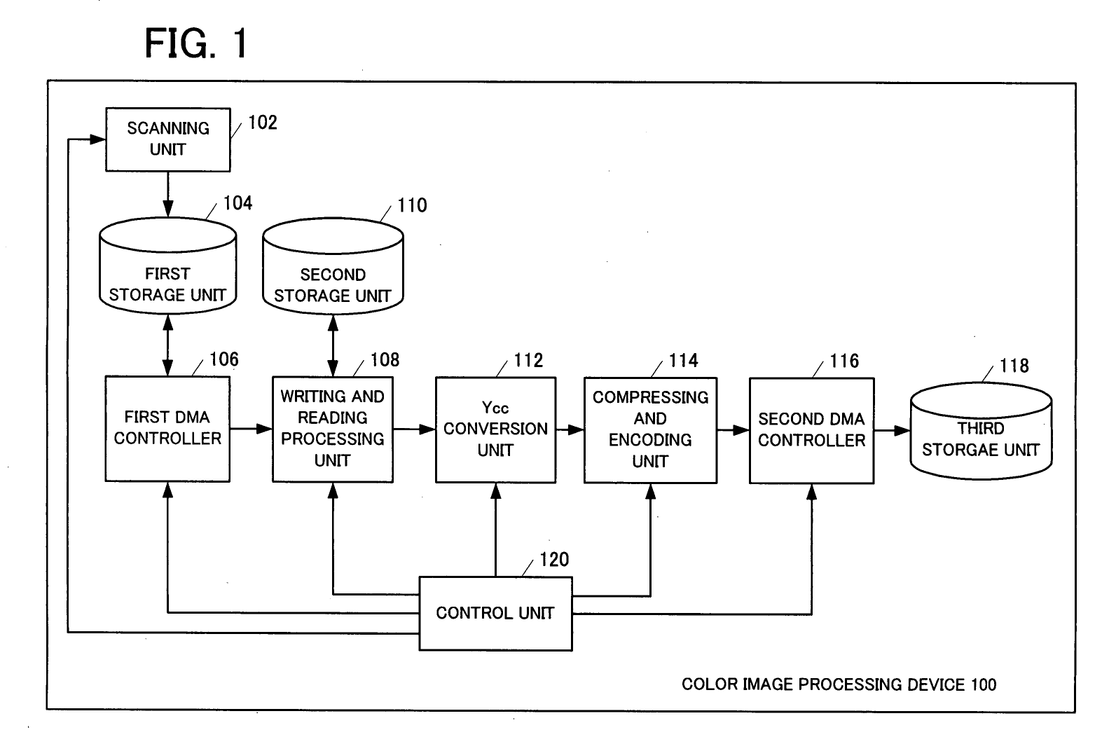

Embodiments of the present invention will be described with reference to the drawings. FIG. 1 is a functional block diagram showing a color image processing device according to an embodiment of the present invention. In the present embodiment, a color image processing device 100 includes a scanner function and a copy function. FIG. 1 shows principal elements relating to the present invention. Although not shown in the drawing, the color image processing device 100 includes a configuration of a general copy machine such as an operation panel and a paper feed unit. The color image processing device 100 can further include a configuration for implementing a communication function such as a facsimile communication function.

In the color image processing device 100, a control unit 120 controls various elements shown in FIG. 1 and also the entire color image processing device 100.

A scanning unit 102 includes a scanner function. The scanning unit 102 scans an original document and generates color image data of an RGB format (first format) (hereinafter referred to as the “RGB data”). The RGB data is composed of data of three color components (Red, Green and Blue). The scanning unit 102 scans an image for each prescribed line.

A first storage unit 104 stores the RGB data scanned by the scanning unit 102. The first storage unit 104 stores the RGB data under a non-compressed state. The first storage unit 104 is a Synchronous Dynamic Random Access Memory (SDRAM) or the like.

The image data stored in the first storage unit 104 is transferred to an YCC conversion unit 112 and a compressing and encoding unit 114. As described above, the YCC conversion unit 112 carries out a color space conversion and a compressing and encoding process of the image data by units of blocks. Therefore, conventionally, a transfer timing was necessary to be controlled so that the image data is transferred to the YCC conversion unit 112 by units of blocks. In the present embodiment, the color image processing device 100 includes a second storage unit 110 which temporarily stores the image data transferred from the first storage unit 104. Accordingly, the transfer of the image data from the first storage unit 104 can be controlled easily.

A first DMA controller 106 transfers the RGB data stored in the first storage unit 104 to the second storage unit 110. The first DMA controller 106 transfers each color component data of the RGB data by units of several lines. Further, the data transfer from the first storage unit 104 to the second storage unit 110 is carried out via a general-purpose bus. The second storage unit 110 is an SDRAM or the like. In the present embodiment, the control unit 120 controls the timing in which the first DMA controller 106 transfers the RGB data to the second storage unit 110. The first DMA controller 106 does not transfer the RGB data stored in the first storage unit 104 continuously to the second storage unit 110 but transfers the RGB data for each prescribed unit (for each prescribed line). Accordingly, even when the data is transferred from the first storage unit 104 to the second storage unit 110 via the general-purpose bus, the general-purpose bus is not occupied by the transfer process carried out by the first DMA controller 106. As a result, the general-purpose bus can be shared with another system. The second storage unit 110 includes a plurality of banks for respectively storing each of R data, G data and B data transferred from the first storage unit 104.

A writing and reading processing unit 108 controls a writing of the RGB data into the second storage unit 110. The writing and reading processing unit 108 also controls a reading of the RGB data from the second storage unit 110. In the present embodiment, the writing and reading processing unit 108 writes the RGB data into different banks for each of the R data, the G data and the B data. The writing and reading processing unit 108 counts a volume of the data transferred by the first DMA controller 106. When the data necessary for forming a block of a prescribed size (here, 64 pixels of 8*8) is written into the second storage unit 110, the writing and reading processing unit 108 starts to transfer the data from the second storage unit 110 to the YCC conversion unit 112. The writing and reading processing unit 108 transfers the RGB data by units of blocks from the second storage unit 110 to the YCC conversion unit 112. The processing carried out by the writing and reading processing unit 108 will be described later in detail.

As described above, the data transferred from the first storage unit 104 is written once in the second storage unit 110. Therefore, the data can be transferred from the first storage unit 104 to the second storage unit 110 without considering a reading speed or a transfer speed from the first storage unit 104.

From the first aspect of the present invention, the writing and reading processing unit 108 and the second storage unit 110 may not be provided in the color image processing device 100. In case of not providing the writing and reading processing unit 108 and the second storage unit 110, the first DMA controller 106 transfers the RGB data from the first storage unit 104 to the YCC conversion unit 112. In this case, the control unit 120 also controls the transfer timing of the first DMA controller 106.

The YCC conversion unit 112 converts the RGB data into color image data of an YCC (luminance color difference) format (second format) (hereinafter referred to as the “YCC data”) by units of one pixel. The compressing and encoding unit 114 compresses and encodes under the JPEG method, the YCC data output from the YCC conversion unit 112. When the compressing and the encoding of the data of one page completes, the compressing and encoding unit 114 outputs an encoding and compressing process end interruption to the control unit 120.

The second DMA controller 116 transfers to a third storage unit 118, the JPEG data compressed and encoded by the compressing and encoding unit 114. The data transfer from the compressing and encoding unit 114 to the third storage unit 118 is also carried out via the general-purpose bus. The third storage unit 118 is also an SDRAM or the like.

In the present embodiment, the control unit 120 controls the timing in which the second DMA controller 116 transfers to the third storage unit 118, the JPEG data compressed and encoded by the compressing and encoding unit 114. Accordingly, even when transferring the data from the compressing and encoding unit 114 via the general-purpose bus to the third storage unit 118, the general-purpose bus is not occupied by the transfer process carried out by the second DMA controller 116. Therefore, the general-purpose bus can be shared with another system. The details of this process will be described later.

The third storage unit 118 stores the JPEG data. The JPEG data stored in the third storage unit 118 is output from a data output unit (not shown) via a Local Area Network (LAN), a Universal Serial Bus (USB) or the like to a personal computer or the like.

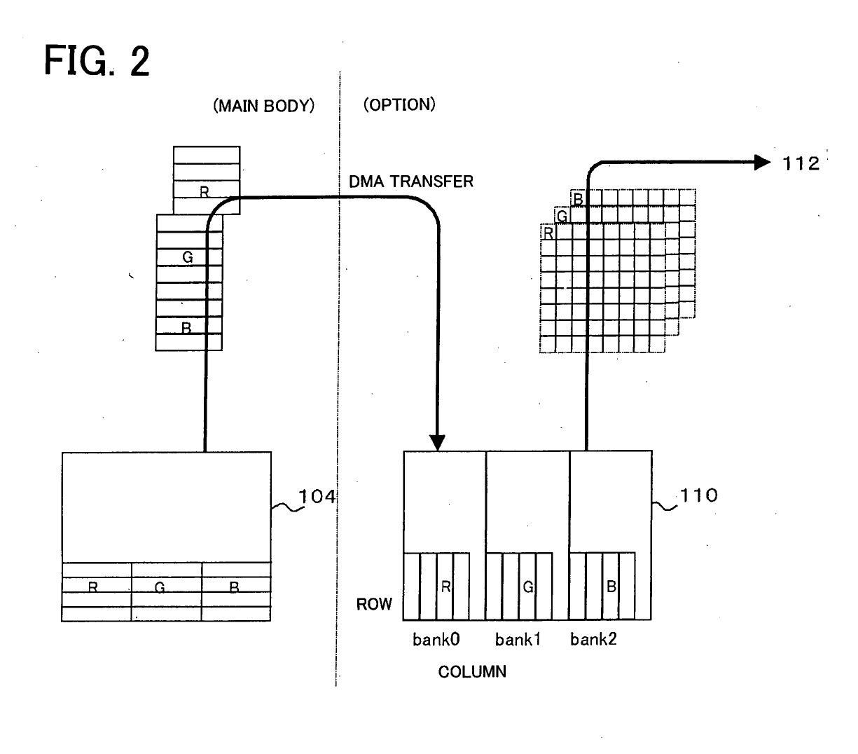

FIG. 2 schematically shows the data transfer carried out in the color image processing device 100. The second storage unit 110, the YCC conversion unit 112 and the compressing and encoding unit 114 or the like are mounted on an option board.

The first DMA controller 106 sequentially transfers the R data, the G data and the B data stored in the first storage unit 104 for each unit of several lines.

The second storage unit 110 includes a plurality of banks 0 through 2 in which the R data, the G data and the B data are written respectively. The R data is written into the bank 0. The G data is written into the bank 1. The B data is written into the bank 2. Further, the lateral direction of each of the banks indicates a column address and the longitudinal direction indicates a row address.

The writing and reading processing unit 108 writes the pixel data of one line transferred from the first DMA controller 106 into each of the banks 0 through 2 while incrementing the row address for each unit of prescribed pixel (here, 8 pixels). When the data of one line is written, the process proceeds onto the next column. The writing and reading processing unit 108 writes the data of the next line in the same manner. The writing and reading processing unit 108 writes the data of eight lines into the banks 0 through 2 as described above so that the data of the same block is stored in the same row address. Then, the writing and reading processing unit 108 fixes the row address and reads the data of eight columns (64 pixels) from the second storage unit 110. Accordingly, the data of a block of a prescribed size (64 pixels) can be read. Without changing the row address, the data can be read from the second storage unit 110 by units of blocks. Therefore, a period of time required for reading the data can be reduced and the data can be processed rapidly.

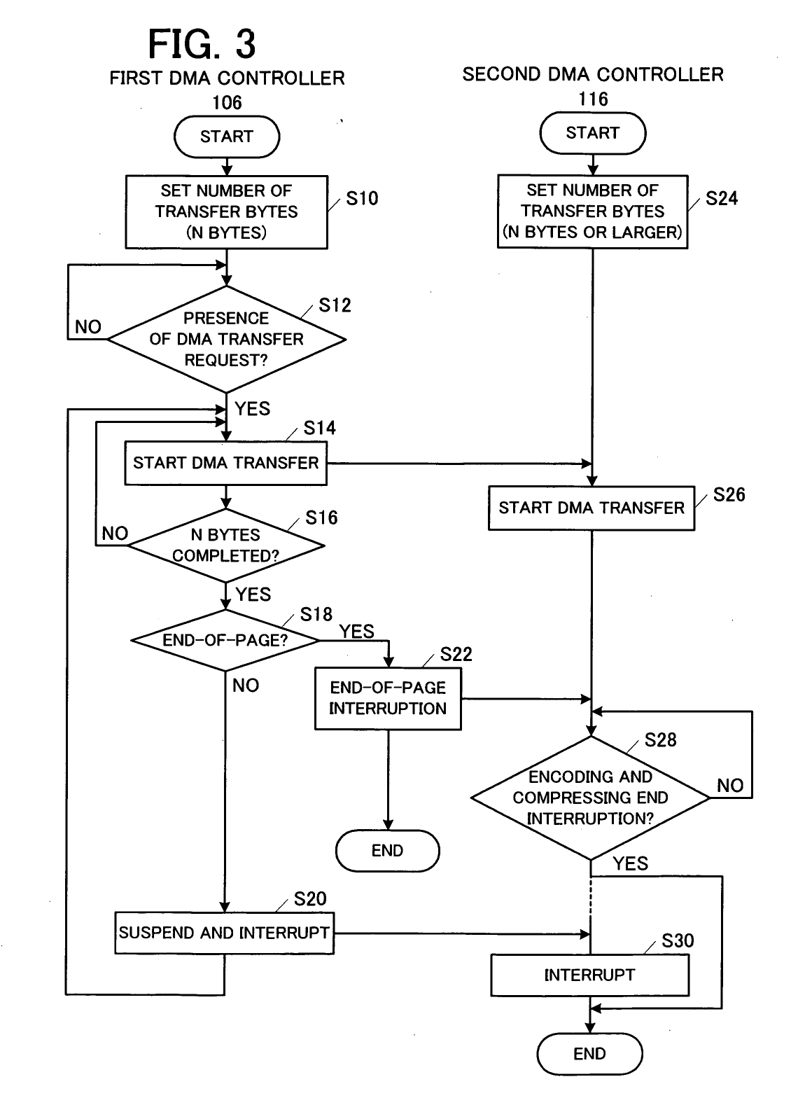

Next, referring to FIG. 3, a description will be made of a procedure in which the control unit 120 controls the timing for transferring the JPEG data from the compressing and encoding unit 114 to the third storage unit 118. Further, the scanning unit 102 scans an original document of units of pages for each line.

FIG. 3 is a flowchart showing processing procedures of the first DMA controller 106 and the second DMA controller 116.

First, a number of transfer bytes is set in the first DMA controller 106 and the second DMA controller 116, respectively (steps S10 and S24). The first DMA controller 106 sets the number of transfer bytes at N bytes. The N bytes can be a data volume of a prescribed line of the original document. The second DMA controller 116 sets the number of transfer bytes at maximum bytes (N bytes or larger).

The first DMA controller 106 monitors a DMA transfer request from the control unit 120 (step S12). When receiving the DMA transfer request from the control unit 120 (YES at step S12), the first DMA controller 106 starts the DMA transfer (step S14). The second DMA controller 116 also starts the DMA transfer (step S26).

In the first DMA controller 106, a determination of whether or not the DMA transfer of N bytes has been completed is monitored (step S16). When the DMA transfer of N bytes has been completed (YES at step S16), a determination is made as to whether or not the DMA transfer of one page has been completed (step S18). When the DMA transfer of one page has not been completed (NO at step S18), the first DMA controller 106 suspends and interrupts the control unit 120 (step S20). That is, the first DMA controller 106 outputs an interruption signal to the control unit 120. Accordingly, the control unit 120 interrupts the DMA transfer of the second DMA controller 116 (step S30). Then, the process returns to step S14 again. In accordance with the DMA transfer request from the control unit 120, the first DMA controller 106 and the second DMA controller 116 start the DMA transfer (steps S14 and S26).

Meanwhile, at step S18, when the DMA transfer of one page has been completed (YES at step S18), the first DMA controller 106 carries out an end-of-page interruption to the control unit 120 (step S22). That is, the first DMA controller 106 outputs a transfer end signal to the control unit 120. When receiving the end-of-page interruption of step S22, the control unit 120 continues the DMA transfer until receiving an encoding and compressing process end interruption from the compressing and encoding unit 114. That is, the control unit 120 continues the DMA transfer until receiving a compressing and encoding end signal. When receiving the encoding and compressing process end interruption from the compressing and encoding unit 114 (YES at step S28), the processing of this page ends.

As described above, in the present embodiment, the compressed and encoded data is divided and transferred by corresponding to the timing in which the image data before the compressing and encoding process is divided and transferred by a prescribed unit. Therefore, the compressed and encoded data can be transferred at appropriate times. Accordingly, even when the data volume of the compressed and encoded data cannot be grasped previously, the data of an appropriate data volume can be transferred sequentially.

In the present embodiment, the data compressed and encoded by the compressing and encoding unit 114 is divided into an appropriate unit and transferred to the third storage unit 118. Therefore, even when using the general-purpose bus, the general-purpose bus is not occupied by the transfer process carried out by the second DMA controller 116. As a result, the general-purpose bus can be shared with another system.

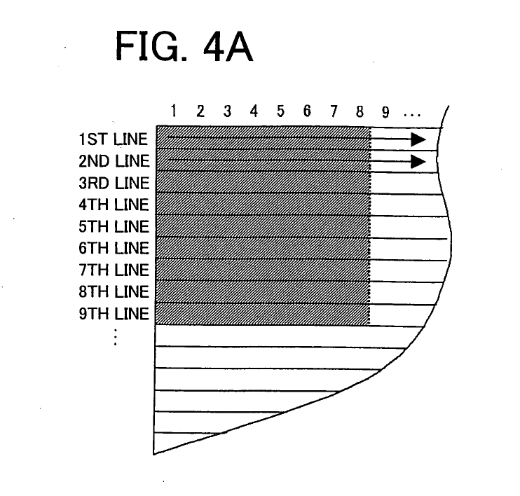

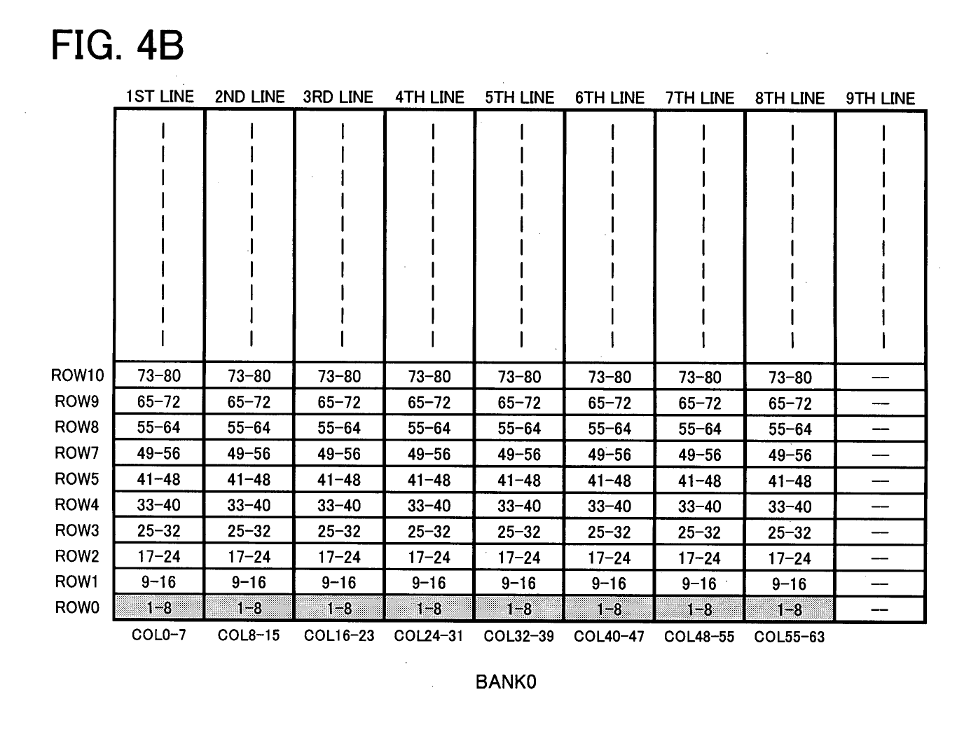

FIGS. 4A and 4B show an inner configuration of the second storage unit 110. FIG. 4A shows an original document scanned by the scanning unit 102. In the following, a description will be made of an example in which data of a shaded area in the drawing (64 pixels of 8*8) is written into the second storage unit 110. The scanning unit 102 scans the original document by units of lines. The first DMA controller 106 also transfers the image data to the second storage unit 110 by units of lines.

FIG. 4B shows an example of the image data written into the second storage unit 110 by the writing and reading processing unit 108. FIG. 4B shows an example of the bank 0. The writing and reading processing unit 108 sections for each of the eight pixels, the pixels of a first line of the image data transferred from the first DMA controller 106 by units of lines. With a column COLO-7 fixed, by sequentially incrementing the row address, the writing and reading processing unit 108 writes the image data into the bank 0. That is, the image data of the first line is stored in the column COLO-7. In the same manner, the writing and reading processing unit 108 sections pixels of a second line for each of the eight pixels. With a column COL8-15 fixed, by sequentially incrementing the row address, the writing and reading processing unit 106 writes the image data into the bank 0. Accordingly, the image data of the second line is stored into the column 8-15. By repeating the same processing until pixels of an eighth line are stored, the pixels of the shaded area of FIG. 4A are stored in a row ROW0 shown in the shaded boxes of FIG. 4B. That is, all of the data of the same block is written into the same row address.

When the row address is fixed to the row ROW0 and the writing and reading processing unit 108 reads the data of the first line through the eighth line, the data of the block of the prescribed size can be obtained. Accordingly, when carrying out a color space conversion and a compressing and encoding process by units of blocks in the YCC conversion unit 112 and the compressing and encoding unit 114, the image data can be read efficiently and transferred rapidly.

As described above, in the color image processing device 100 of the present embodiment, with the column address fixed, the writing and reading processing unit 108 sequentially writes the image data read from the first storage unit 104 to each of the banks of the second storage unit 110. Therefore, when reading, the image data of units of blocks can be read under a state in which the row address is fixed. Thus, the image data of units of blocks can be read rapidly from the second storage unit 110 and transferred to the YCC conversion unit 112. Accordingly, the processing in the YCC conversion unit 112 and the compressing and encoding unit 114 can be carried out efficiently.

A preferred embodiment of the present invention has been described. However, the present invention is not limited to the above-described embodiment. It is to be understood by those skilled in the art that there are variations to the embodiment without departing from the scope of the present invention.

In the above-described example, the RGB data is converted into the YCC data and the compressing and encoding process is carried out. However, for example, the RGB data can be converted into Lab data and the compressing and encoding process can be carried out. That is, the color space before and after the conversion by the conversion unit 112 is not limited to the RGB format and the YCC format.

The YCC conversion unit 112 may not be provided in the color image processing device 100. In this case, the compressing and encoding unit 114 can carry out the compressing and encoding process directly on the RGB data transferred from the first storage unit 104.

The present invention can provide a preferable and useful data transfer technology applied in the color image processing device.

1. A color image processing device, comprising:
a first transfer control means for transferring image data of a prescribed volume for each prescribed unit;
means for compressing and encoding the image data;
means for storing data compressed and encoded by the means for compressing and encoding; and
a second transfer control means for transferring the compressed and encoded data from the means for compressing and encoding to the means for storing,
wherein each time when the first transfer control means transfers the image data of the prescribed unit, the second transfer control means divides and transfers the compressed and encoded data.

2. The color image processing device according to claim 1, wherein each time when the first transfer control means transfers the image data of the prescribed unit, the first transfer control means transmits an interruption signal to the second transfer control means; and
each time when the second transfer control means receives the interruption signal from the first transfer control means, the second transfer control means stops to transfer the image data.

3. The color image processing device according to claim 2, wherein when the transfer of all of the image data of the prescribed volume completes, the first transfer control means transmits a transfer end signal to the second transfer control means;
when a compressing and encoding process of all of the image data of the prescribed volume completes, the means for compressing and encoding transmits a compressing and encoding end signal to the second transfer control means; and
after receiving the transfer end signal from the first transfer control means, the second transfer control means continues to transfer the image data until receiving the compressing and encoding end signal from the means for compressing and encoding.

4. A color image processing device, comprising:
means for inputting color image data of a first format;
a first storing means for storing the input color image data of the first format;
a second storing means;
a first transfer control means for transferring the color image data of the first format by units of a prescribed line from the first storing means to the second storing means;
a writing and reading processing means for controlling a writing of the color image data of the first format to the second storing means and a reading of the color image data of the first format from the second storing means;
means for converting the color image data of the first format into color image data of a luminance color difference format;
means for compressing and encoding the color image data of the luminance color difference format;
a third storing means for storing the color image data compressed and encoded by the means for compressing and encoding; and
a second transfer control means for transferring the compressed and encoded color image data from the means for compressing and encoding to the third storing means,
wherein each time when the first transfer control means transfers the color image data for the prescribed line, the second transfer control means divides and transfers the compressed and encoded color image data.

5. The color image processing device according to claim 4, wherein each time when the first transfer control means transfers the color image data for the prescribed line, the first transfer control means transmits an interruption signal to the second transfer control means; and
each time when the second transfer control means receives the interruption signal from the first transfer control means, the second transfer control means stops to transfer the color image data.

6. The color image processing device according to claim 5, wherein when the transfer of all of the color image data of one page completes, the first transfer control means transmits a transfer end signal to the second transfer control means;
when a compressing and encoding process of all of the color image data of one page completes, the means for compressing and encoding transmits a compressing and encoding end signal to the second transfer control means; and
after receiving the transfer end signal from the first transfer control means, the second transfer control means continues to transfer the color image data until receiving the compressing and encoding end signal from the means for compressing and encoding.

7. The color image processing device according to claim 4, wherein the writing and reading processing means counts a data volume of the color image data transferred by the first transfer control means, and when data necessary for forming a block of a prescribed size is written into the second storing means, the writing and reading processing means starts to transfer the color image data from the second storing means to the means for converting.

8. A color image processing method, comprising:
transferring non-compressed image data for each prescribed unit and storing the image data in a storage unit;
compressing and encoding the image data;
transferring the compressed and encoded image data and storing the image data in the storage unit; and
dividing and transferring the compressed and encoded image data each time when transferring the non-compressed image data for the prescribed unit.

9. A color image processing method, comprising:
transmitting an interruption signal each time when transferring non-compressed image data for a prescribed unit;
compressing and encoding the non-compressed image data;
transferring the compressed and encoded image data and storing the compressed and encoded image data in a storage unit; and
dividing and transferring the compressed and encoded image data each time when transferring the non-compressed image data for the prescribed unit by stopping to transfer the compressed and encoded image data each time when receiving the interruption signal.

10. The color image processing method according to claim 9 further comprising:
transmitting a transfer end signal when the transferring of all of the non-compressed image data of one page completes;
transmitting a compressing and encoding end signal when the compressing and encoding of all of the image data of one page completes; and
continuing to transfer the compressed and encoded image data until receiving the compressing and encoding end signal after receiving the transfer end signal.

11. A color image processing device, comprising:
a first storing means for storing image data composed of a plurality of color components;
a transfer control means for controlling a transfer of the image data;
a second storing means for storing the image data transferred from the first storing means by the transfer control means for each of the color components; and
means for compressing and encoding the image data by units of blocks,
wherein the transfer control means reads the image data of units of blocks for all of the plurality of the color components from the second storing means and transfers the image data to the means for compressing and encoding.

12. The color image processing device according to claim 11, further comprising:
an access means for controlling a writing of the image data to the second storing means and a reading of the image data from the second storing means,
wherein the second storing means includes a plurality of banks which respectively stores image data for each of the plurality of the color components and is accessed by the access means in accordance with a row address and a column address; and
the access means writes the color image data into the second storing means so that data of a same block is stored in a same row address.

13. The color image processing device according to claim 12, wherein with the row address fixed, the access means reads the image data of units of blocks from each of the plurality of the banks and transfers the image data to the means for compressing and encoding.

14. A color image processing device, comprising:
means for inputting color image data of a first format formed of a plurality of color components;
a first storing means for storing the input color image data of the first format;
a second storing means for storing the color image data of the first format;
a first transfer control means for transferring the color image data of the first format from the first storing means to the second storing means for each of the color components;
a writing and reading processing means for controlling a writing of the color image data of the first format to the second storing means and a reading of the color image data of the first format from the second storing means;
means for converting the color image data of the first format into color image data of a luminance color difference format; and
means for compressing and encoding the color image data of the luminance color difference format by units of blocks,
wherein the writing and reading processing means reads the color image data by units of blocks for each of the color components from the second storing means and transfers the color image data to the means for converting.

15. The color image processing device according to claim 14, wherein the second storing means includes a plurality of banks which respectively stores the color image data for each of the plurality of the color components and is accessed by the writing and reading processing means in accordance with a row address and a column address; and
the writing and reading processing means writes the color image data into the second storing means so that data of a same block is stored in a same row address.

16. The color image processing device according to claim 15, wherein with the row address fixed, the writing and reading processing means reads the color image data of units of blocks from each of the plurality of the banks and transfers the color image data to the means for converting.

17. A color image processing method, comprising:
inputting non-compressed image data composed of a plurality of color components;
storing the input image data under a non-compressed state in a first storage unit;
transferring the non compressed image data stored in the first storage unit for each of the color components and storing the non-compressed image data in a second storage unit;
reading the non-compressed image data from the second storage unit for each of the color components by units of blocks and transferring the non-compressed image data to a compressing and encoding unit; and
compressing and encoding the input non-compressed image data by units of blocks.

18. The color image processing method according to claim 17, wherein in the step of transferring and storing, the non-compressed image data is written into the second storage unit so that different banks store each of the color components and data of a same block is stored in a same row address; and
in the step of transferring, under a state in which the row address is fixed in the same block, the non-compressed image data for each of the color components is read by units of blocks from each of the banks and is transferred.

19. A color image processing device, comprising:
a first transfer control unit that transfers image data of a prescribed volume for each prescribed unit;
a compressing and encoding unit that compresses and encodes the image data;
a storage unit that stores the data compressed and encoded by the compressing and encoding unit; and
a second transfer control unit that transfers the compressed and encoded data from the compressing and encoding unit to the storage unit,
wherein each time when the first transfer control unit transfers the image data of the prescribed unit, the second transfer control unit divides and transfers the compressed and encoded data.

20. The color image processing device according to claim 19, wherein each time when the first transfer control unit transfers the image data of the prescribed unit, the first transfer control unit transmits an interruption signal to the second transfer control unit; and
each time when the second transfer control unit receives the interruption signal from the first transfer control unit, the second transfer control unit stops to transfer the image data.
